(19) United States
(12) Patent Application Publication
(10) Pub. No.: US 2012/0153406 A1
(43) Pub. Date: Jun. 21, 2012

(54) SEMICONDUCTOR DEVICE AND METHOD FOR FABRICATING THE SAME

(76) Inventors: Woo-Young PARK, Gyeonggi-do (KR); Kee-Jeung Lee, Gyeonggi-do (KR); Tae-Yoon Kim, Gyeonggi-do (KR); Yun-Hyuck Ji, Gyeonggi-do (KR)

(21) Appl. No.: 13/223,542

(22) Filed: Sep. 1, 2011

(30) Foreign Application Priority Data
Dec. 15, 2010 (KR) 10-2010-0128321

(51) Int. Cl. H01L 29/772; H01L 21/28

(52) U.S. Cl. 257/410; 438/591; 257/E21.19; 257/E29.242

(57) ABSTRACT

A method for fabricating a semiconductor device includes forming a gate dielectric layer over a substrate, forming a dipole capping layer over the gate dielectric layer, stacking a metal gate layer and a polysilicon layer over the dipole capping layer, and forming a gate pattern by etching the polysilicon layer, the metal gate layer, the dipole capping layer, and the gate dielectric layer.

### CROSS-REFERENCE TO RELATED APPLICATIONS

The present application claims priority of Korean Patent Application No. 10-2010-0128321, filed on Dec. 15, 2010, which is incorporated herein by reference in its entirety.

### BACKGROUND

1. Field

Exemplary embodiments of the present invention relate to a semiconductor fabrication technology, and more particularly, to a semiconductor device and a method for fabricating the same.

2. Description of the Related Art

With the development of technology, the integration degree of elements is increasing twofold every two years, and currently, under-45 nm processes are used. In the case of DRAMs, the cell size has been reduced to less than 100 nm. By using nano-size elements, high integration, high driving speed, and low power consumption are achieved.

As the gate elements of DRAM and logic devices are reduced in size, obtaining a sufficient drain current is a significant issue because of a limit in channel widths. Furthermore, an increase in leakage current due to a reduction in thickness of a gate dielectric layer may interfere with device operations. Therefore, a method of reducing a leakage current is useful.

Accordingly, a method of using a gate material as a gate dielectric layer with a higher dielectric constant is being developed. For example, as a material having a dielectric constant larger than 3.9 and multi-functional properties including thermal stability at high temperature, hafnium silicate, hafnium silicon oxynitride, hafnium oxide or the like may be used as the gate dielectric layer.

However, when a hafnium-based dielectric is used in fabricating NMOS and PMOS elements, a threshold voltage may vary. The threshold voltage variation may occur when the Fermi level of polysilicon is pinned immediately below a conduction band by an interaction between the hafnium-based gate dielectric and the polysilicon interface. This phenomenon is referred to Fermi level pinning and causes a threshold voltage variation. In particular, a variation in threshold voltage and flat-band voltage of the PMOS element is larger than that of the NMOS element due to Fermi level pinning.

When a high-k gate is used as a gate dielectric layer in the NMOS element, a metal gate having a low work function is to be used to suppress a threshold voltage variation. However, polysilicon is used as a gate conductor of the NMOS element for obtaining stable operations despite thermal degradation of the metal gate having a low work function and for reducing process complexity due to the use of dual metals.

However, since a silicide reaction occurring at the interface between the polysilicon and the gate dielectric deteriorates the above-described structure, polysilicon is not used.

In the case of the PMOS element, when a high-k gate dielectric is used as a gate dielectric layer, a threshold voltage variation may be largely controlled by forming a metal gate having a high work function, such as titanium aluminum nitride (TiAlN), over the gate dielectric. TiAlN exhibits more stable oxidation resistance at high temperature than TiN and maintains electrical conductivity without being oxidized in an oxidation atmosphere.

However, TiAlN becomes oxidized at 700° C. or more, and Al of the metal gate is diffused into a layer where an oxidation reaction may occur. Al may cause an oxidation reaction with oxygen existing in gate oxide under the metal gate, and metal gate elements may be diffused into the gate oxide and the substrate layer to form a trap. Furthermore, the dielectric property of the gate oxide and the property and mobility of the work function of the metal gate may be degraded by the interaction between the gate oxide and the metal gate.

An actual gate element is subjected to a heat treatment process at temperature of 1,000° C., during the source/drain formation. In this case, the interaction between the gate oxide and the metal gate having a high work function such as TiAlN may occur. Therefore, it is useful to have a method and structure capable of substantially preventing the interaction between a high-k gate oxide and a metal gate layer having a high work function while maintaining the stability of the threshold voltage and the flat-band voltage for a PMOS element including the two layers.

### SUMMARY

Exemplary embodiments of the present invention are directed to a semiconductor device capable of stabilizing a threshold voltage and a flat-band voltage and securing the reliability of the device and a method of fabricating the same.

In accordance with an exemplary embodiment of the present invention, a method for fabricating a semiconductor device includes: forming a gate dielectric layer over a substrate; forming a dipole capping layer over the gate dielectric layer; stacking a metal gate layer and a polysilicon layer over the dipole capping layer; and forming a gate pattern by etching the polysilicon layer, the metal gate layer, the dipole capping layer, and the gate dielectric layer.

In accordance with another exemplary embodiment of the present invention, a method for fabricating a semiconductor device include: forming a gate dielectric layer over a substrate having NMOS and PMOS regions; forming dipole capping layers having different thicknesses over the gate dielectric layer in the NMOS and PMOS regions, respectively; forming a metal gate layer over the dipole capping layer of the PMOS region; forming a polysilicon layer over the dipole capping layer of the NMOS region and the metal gate layer of the PMOS region; and forming gate patterns in the NMOS and PMOS regions, respectively, through patterning.

In accordance with yet another exemplary embodiment of the present invention, a semiconductor device includes: a gate dielectric layer formed over a substrate; a dipole capping layer formed over the gate dielectric layer; a metal gate layer formed over the dipole capping layer; and a gate pattern having a polysilicon layer formed over the metal gate layer.

In accordance with still another exemplary embodiment of the present invention, a method for fabricating a semiconductor device include: forming a gate dielectric layer over a substrate having NMOS and PMOS regions; forming a dipole capping layer over the gate dielectric layer in the NMOS and PMOS regions; forming a metal gate layer over the dipole capping layer of the PMOS region; forming a polysilicon layer over the dipole capping layer of the NMOS region and the metal gate layer of the PMOS region; and forming gate patterns in the NMOS and PMOS regions, respectively, through pattering.

### BRIEF DESCRIPTION OF THE DRAWINGS

FIG. 1 is a cross-sectional view illustrating a semiconductor device in accordance with a first exemplary embodiment of the present invention.

FIGS. 2A to 2H are cross-sectional views illustrating a method for fabricating a semiconductor device in FIG. 1 in accordance with the first exemplary embodiment of the present invention.

FIGS. 3A to 3G are cross-sectional views illustrating another method for fabricating a semiconductor device in FIG. 1 in accordance with the first exemplary embodiment of the present invention.

FIG. 4 is a cross-sectional view illustrating a semiconductor device in accordance with a second exemplary embodiment of the present invention.

FIGS. 5A to 5E are cross-sectional views illustrating a method for fabricating a semiconductor device in FIG. 4 in accordance with the second exemplary embodiment of the present invention.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

### First Exemplary Embodiment

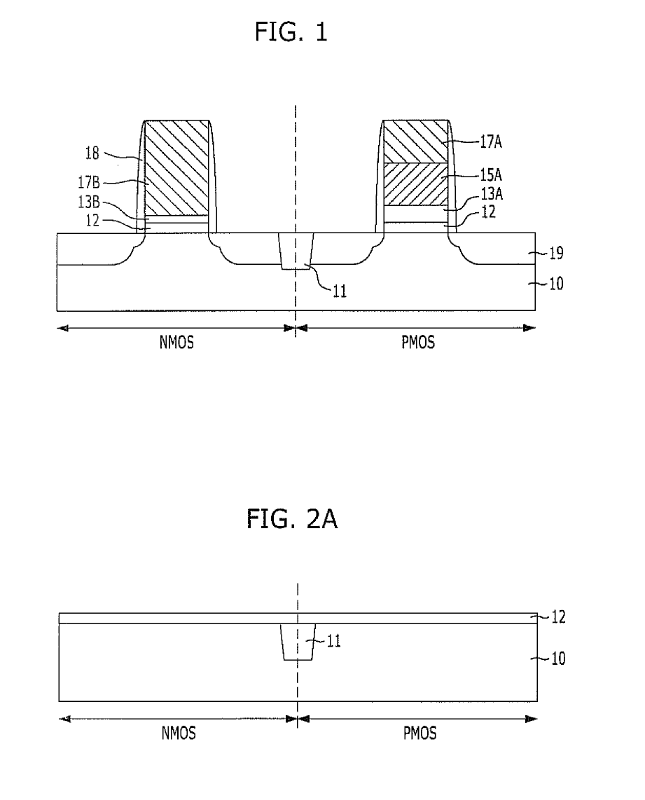

FIG. 1 is a cross-sectional view illustrating a semiconductor device in accordance with a first exemplary embodiment of the present invention.

Referring to FIG. 1, an isolation layer 11 is formed in a substrate 10 having NMOS and PMOS regions, and gate patterns are formed on the substrate 10 at the NMOS and PMOS regions, respectively.

The gate pattern of the NMOS region has a stacked structure of a gate dielectric layer 12, a second dipole capping layer 13B having a smaller thickness than a first dipole capping layer 13A, and a polysilicon gate 17B, and the gate pattern of the PMOS region has a stacked structure of the gate dielectric layer 12, the first dipole capping layer 13A, a metal gate layer 15A, and a polysilicon gate 17A.

A gate spacer 18 is formed on sidewalls of the respective gate patterns of the NMOS and PMOS regions, and a source/drain region 19 is formed in the substrate 10 at both sides of the gate pattern.

The gate dielectric layer 12 of the NMOS and PMOS regions includes a single layer or multilayer. For example, the gate dielectric layer 12 has a single layer structure of a high-k dielectric layer or a multilayer structure including a high-k dielectric layer. The multilayer structure may include a structure in which a high-k dielectric layer is stacked on an oxide silicon layer (SiO₂) or an oxynitride silicon layer (SiON). According to an example, the oxide silicon layer or oxynitride silicon layer is formed to a thickness of 1 nm or less.

Furthermore, the high-k dielectric layer is formed of a dielectric material having a dielectric constant of 3.9 or more. For example, the high-k dielectric layer includes any one layer or two or more layers selected from the group consisting of hafnium silicate, hafnium silicon oxynitride, hafnium oxide, zirconium oxide, titanium oxide, lanthanum oxide, hafnium aluminum oxide, strontium titanium oxide, and is formed to a thickness of 1 nm to 3 nm.

The first and second dipole capping layers 13A and 13B of the PMOS and NMOS regions may be formed of any one selected from the group consisting of aluminum oxide (Al₂O₃), aluminum oxynitride (AlON), and aluminum nitride (AlN).

The first and second dipole capping layers 13A and 13B of the PMOS and NMOS regions are formed to different thicknesses. According to an example, the second dipole capping layer 13B of the NMOS region is formed to a thickness equal to or less than a dipole critical thickness (for example, a thickness of 0.3 nm or less), and the first dipole capping layer 13A of the PMOS region is formed to more than the dipole critical thickness (for example, a thickness of 0.5 nm to 1.5 nm).

The metal gate layer 15A of the PMOS region includes any one layer or two or more layers selected from the group consisting of titanium nitride, titanium aluminum nitride, tantalum nitride, titanium silicon nitride, tantalum silicon nitride, tantalum titanium nitride, titanium silicide, and hafnium nitride.

As the first and second dipole capping layers 13A and 13B having different thicknesses are formed in the PMOS and NMOS regions, respectively, an interaction and diffusion between the gate dielectric layer 12 and the gate conductor (the polysilicon gate of the NMOS region and the metal gate layer of the PMOS region) is substantially prevented, and a threshold voltage Vt and a flat-band voltage Vfb are stabilized.

In particular, the first dipole capping layer 13A of the PMOS region is formed to more than the dipole critical thickness to stabilize the threshold voltage and the flat-band voltage. Simultaneously, the first dipole capping layer 13A of the NMOS region is formed to the dipole critical thickness or less to substantially prevent the degradation of the threshold voltage and the flat-band voltage caused by a P-type capping effect.

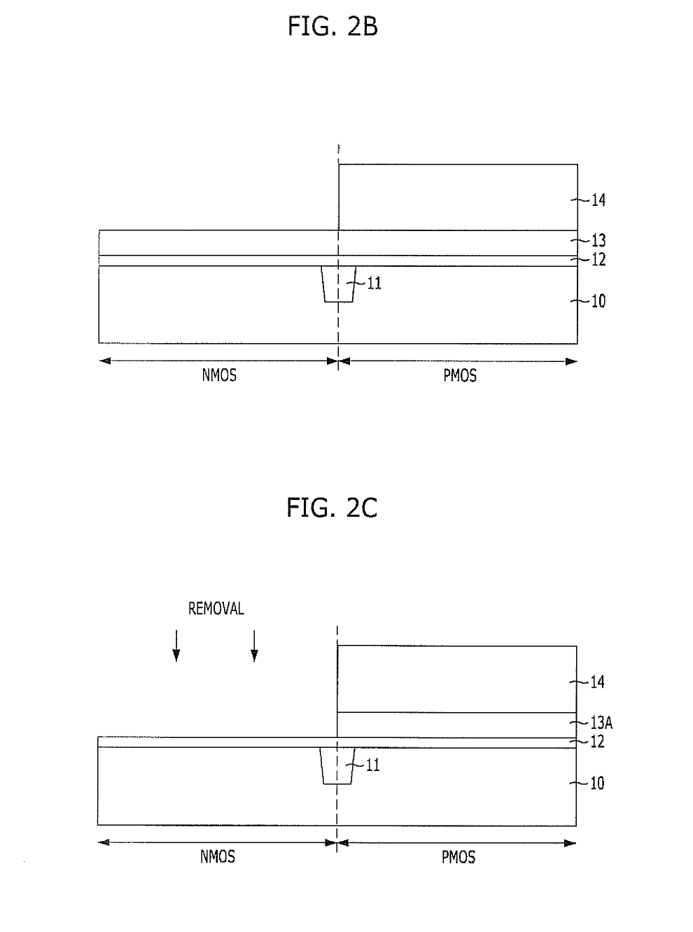

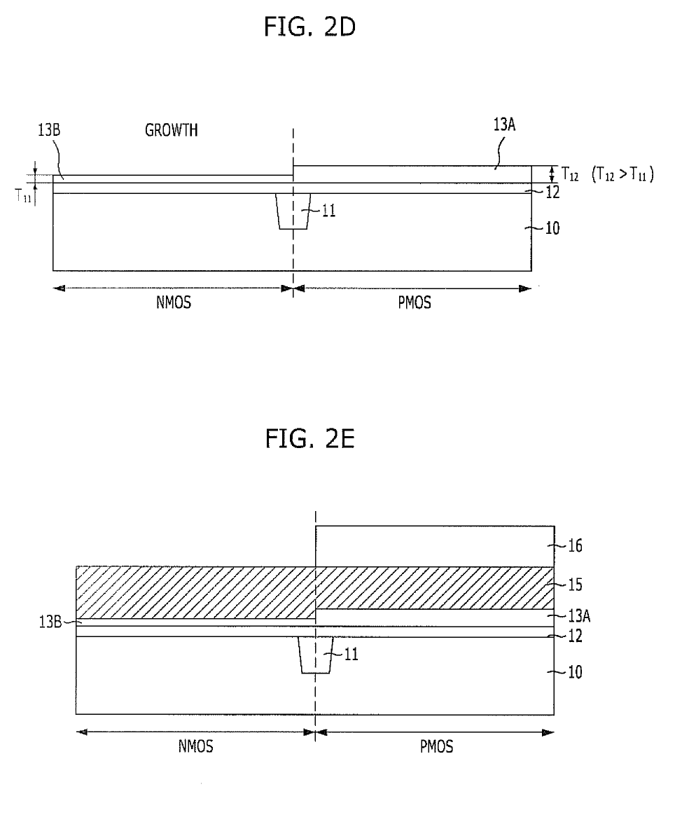

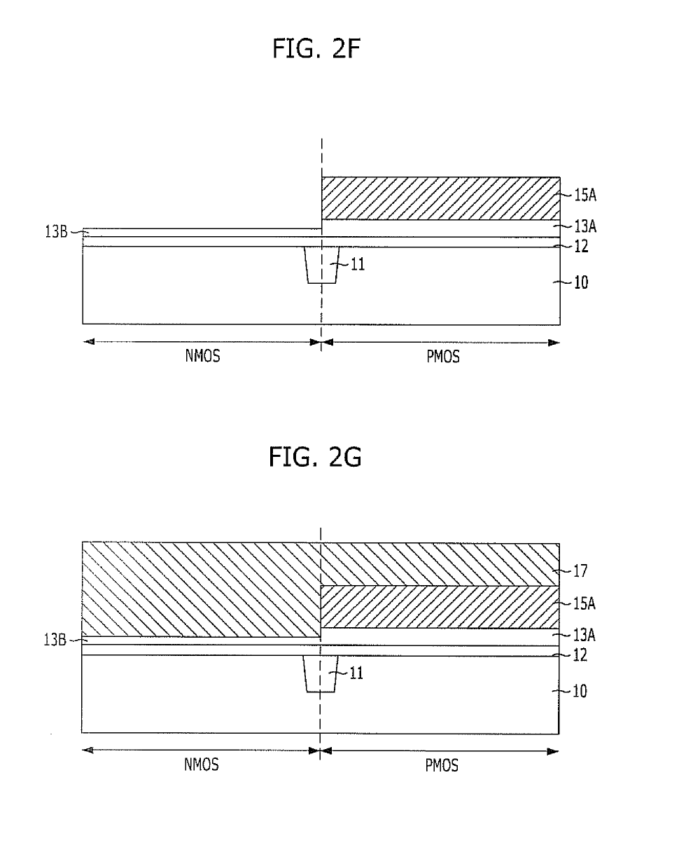

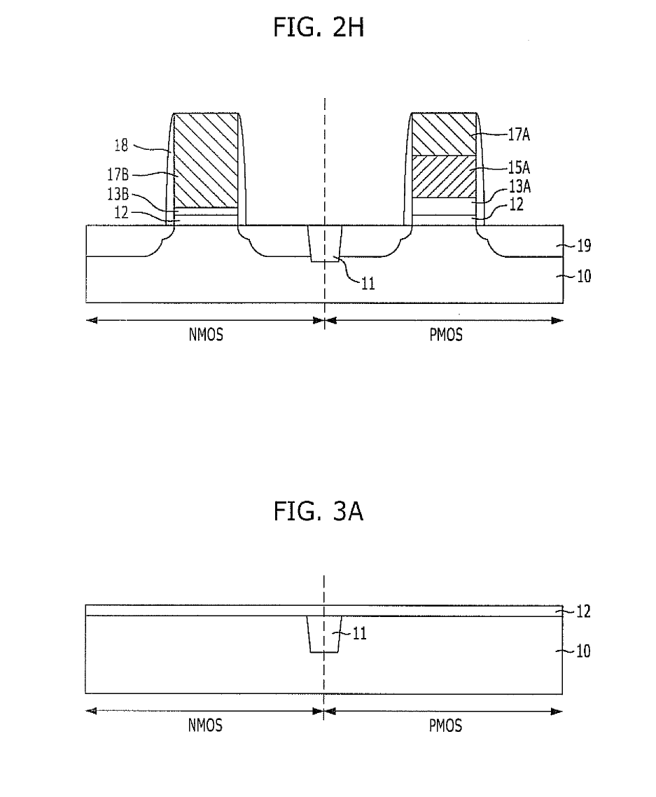

FIGS. 2A to 2H are cross-sectional views illustrating a method for fabricating a semiconductor device in FIG. 1 in accordance with the first embodiment of the present invention. For purposes of illustration, the same reference numerals as those of FIG. 1 will be used.

Referring to FIG. 2A, an isolation layer 11 is formed in a substrate 10 having NMOS and PMOS regions. The isolation layer 11 may be formed by a shallow trench isolation (STI) process.

A gate dielectric layer 12 is formed on the substrate 10. The gate dielectric layer 12 includes a single layer or multiple layers. For example, the gate electric layer 12 may have a single layer structure of a high-k dielectric layer or a multilayer structure including a high-k dielectric layer. The multilayer structure may include a structure in which a high-k dielectric layer is stacked on an oxide silicon layer (SiO₂) or oxynitride silicon layer (SiON). At this time, the oxide silicon layer or oxynitride silicon layer is formed to a thickness of 1 nm or less.

Furthermore, the high-k dielectric layer is formed of a dielectric material having a dielectric constant of 3.9 or more. For example, the high-k dielectric layer may include any one layer or two or more layers selected from the group consisting of hafnium silicate, hafnium silicon oxynitride, hafnium oxide, zirconium oxide, titanium oxide, lanthanum oxide, hafnium aluminum oxide, strontium titanium oxide, and is formed to a thickness of 1 nm to 3 nm.

Referring to FIG. 2B, a dipole capping layer 13 is formed on the gate dielectric layer 12. The dipole capping layer 13 serves to substantially prevent an interaction between the gate dielectric layer 12 and a subsequent gate conductor and stabilize a threshold voltage and a flat-band voltage by differentiating a dipole capping effect.

The dipole capping layer 13 is formed of a metal insulator. According to an example, the metal insulator may include any one selected from the group consisting of aluminum oxide (Al₂O₃), aluminum oxynitride (AlON), and aluminum nitride (AlN), and is formed to a thickness of 0.5 nm to 1.5 nm.

A first mask pattern 14 is formed on the dipole capping layer 13 of the PMOS region. The first mask pattern 14 serves to protect the dipole capping layer 13 of the PMOS region and is provided to selectively remove only the capping layer 13 of the NMOS region. The first mask pattern 14 is formed of a material having an etching selectivity with the dipole capping layer 13.

Referring to FIG. 2C, the dipole capping layer 13 (refer to FIG. 2B) of the NMOS region is selectively removed. Therefore, the dipole capping layer 13 remains only on the gate dielectric layer 12 of the PMOS region, and the remaining dipole capping layer 13 is referred to as a first dipole capping layer 13A.

Referring to FIG. 2D, a second dipole capping layer 13B is grown on the gate dielectric layer 12 of the NMOS region. The second dipole capping layer 13B may be formed of the same material as or a different material from the first dipole capping layer 13A. That is, the second dipole capping layer 13B may be formed of the same material as the first dipole capping layer, but may be formed to a dipole critical thickness or less so that a P-type dipole effect is not exhibited. Alternatively, the second dipole capping layer 13B may be formed of an N-type dipole capping layer.

The second dipole capping layer 13B formed of the same material as the first dipole capping layer 13A may be formed to a smaller thickness than the first dipole capping layer 13A. Here, when the thickness of the first dipole capping layer 13A is represented by T₁₂ and the thickness of the second dipole capping layer 13B is represented by T₁₁, a relation of T₁₂>T₁₁ may be established. The second dipole capping layer 13B may be formed to the critical thickness or less so that a dipole effect is not exhibited (for example, a thickness of 0.3 nm or less).

Referring to FIG. 2E, a metal gate conductor layer 15 is formed on the first and second dipole capping layers 13A and 13B.

The metal gate conductor layer 15 may include any one layer or two or more layers selected from the group consisting of titanium nitride, titanium aluminum nitride, tantalum nitride, titanium silicon nitride, tantalum silicon nitride, tantalum titanium nitride, titanium silicide, and hafnium nitride.

A second mask pattern 16 is formed on the metal gate conductor layer 15 of the PMOS region. The second mask pattern 16 is formed by the following process: a photoresist layer is applied on the metal gate conductor layer 15 and then patterned through exposure and development so as to remain only on the metal gate conductor layer 15 of the PMOS region.

Referring to FIG. 2F, the metal gate conductor layer 15 (refer to FIG. 2E) of the NMOS region is removed by using the second mask pattern 16 as an etching barrier such that the metal gate conductive layer 15 remains only on the first dipole capping layer 13A of the PMOS region.

The metal gate conductor layer 15 remaining on the first dipole capping layer 13A of the PMOS region is hereafter referred to as metal gate layer 15A.

As the metal gate layer 15A having a high work function is additionally formed in the PMOS region, silicide may be prevented from being formed at the interface with a subsequent polysilicon layer. Therefore, a phenomenon in which a larger threshold voltage variation occurs in the PMOS region than the NMOS region due to Fermi level pinning depending on the silicide may be prevented.

Referring to FIG. 2G, a polysilicon layer 17 is formed on the second dipole capping layer 13B of the NMOS region and the metal gate layer 15A of the PMOS region.

Although not illustrated, ion impurities may be implanted into the polysilicon layer 17 depending on the NMOS region or PMOS region.

Referring to FIG. 2H, patterning is performed on the NMOS region and the PMOS region, respectively, to form gate patterns.

The gate pattern of the NMOS region has a stacked structure of the gate dielectric layer 12, the second dipole capping layer 13B having a smaller thickness than the first dipole capping layer 13A, and the polysilicon gate 17B, and the gate pattern of the PMOS region has a stacked structure of the gate dielectric layer 12, the first dipole capping layer 13A, the metal gate layer 15A, and the polysilicon gate 17A.

A gate spacer 18 is formed on sidewalls of the respective gate patterns of the NMOS and PMOS regions.

Ion impurities are implanted into the substrate 10 at both sides of the gate pattern to form a source/drain region 19.

As the first and second dipole capping layers 13A and 13B having different thicknesses are formed in the PMOS and NMOS regions, respectively, an interaction and diffusion between the gate dielectric layer 12 and the gate conductors (the polysilicon gate of the NMOS region and the metal gate layer of the PMOS region) may be prevented and a threshold voltage Vt and a flat-band voltage Vfb may be stabilized.

In particular, the first dipole capping layer 13A of the PMOS region may be formed to have a thickness larger than the dipole critical thickness to stabilize the threshold voltage and the flat-band voltage through P-type dipole capping. Simultaneously, the first dipole capping layer 13A of the NMOS region may be formed to the dipole critical thickness or less to substantially prevent the degradation of threshold voltage and flat-band voltage caused by a P-type capping effect.

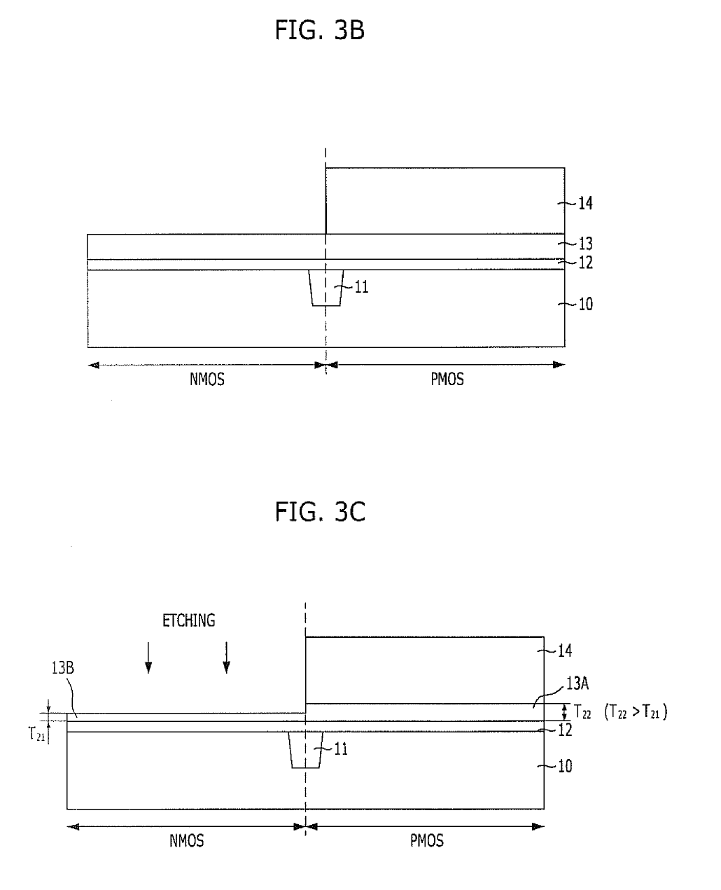

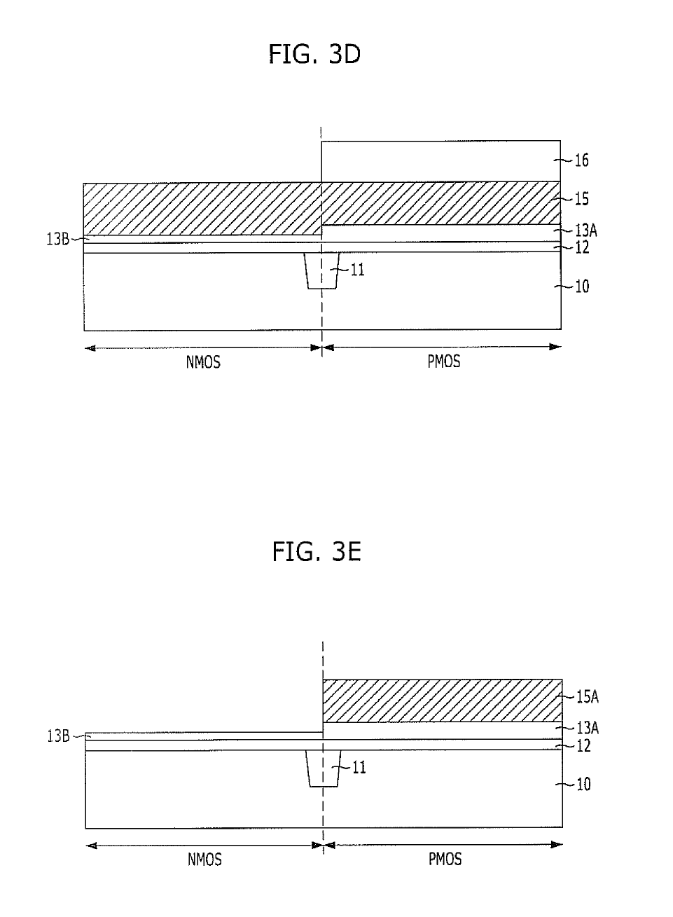

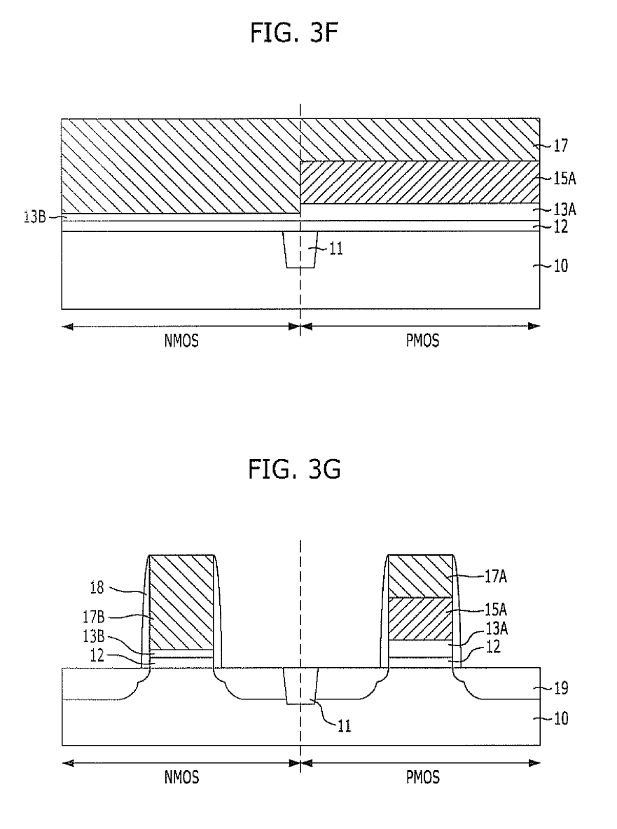

FIGS. 3A to 3G are cross-sectional views illustrating another method for fabricating a semiconductor device in FIG. 1 in accordance with the first embodiment of the present invention. For purposes of illustration, the same reference numerals as those of FIG. 1 will be used.

Referring to FIG. 3A, an isolation layer 11 is formed in a substrate 10 having NMOS and PMOS regions. The isolation layer 11 may be formed by an STI process.

A gate dielectric layer 12 is formed on the substrate 10. The gate dielectric layer 12 includes a single layer or multiple layers. For example, the gate electric layer 12 may have a single layer structure of a high-k dielectric layer or a multilayer structure including a high-k dielectric layer. The multilayer structure may include a structure in which a high-k dielectric layer is stacked on an oxide silicon layer (SiO₂) or oxynitride silicon layer (SiON). At this time, the oxide silicon layer or oxynitride silicon layer is formed to a thickness of 1 nm or less.

Furthermore, the high-k dielectric layer is formed of an insulator having a dielectric constant of 3.9 or more. For example, the high-k dielectric layer may include any one layer or two or more layers selected from the group consisting of hafnium silicate, hafnium silicon oxynitride, hafnium oxide, zirconium oxide, titanium oxide, lanthanum oxide, hafnium aluminum oxide, strontium titanium oxide, and is formed to a thickness of 1 nm to 3 nm.

Referring to FIG. 3B, a dipole capping layer 13 is formed on the gate dielectric layer 12. The dipole capping layer 13 serves to substantially prevent an interaction between the gate dielectric layer 12 and a subsequent gate conductor and stabilize a threshold voltage and a flat-band voltage by differentiating a dipole capping effect.

The dipole capping layer 13 is formed of any one selected from the group consisting of Al₂O₃, AlON, and AlN, for example, and is formed to a thickness of 0.5 nm to 1.5 nm.

A first mask pattern 14 is formed on the dipole capping layer 13 of the PMOS region. The first mask pattern 14 serves to protect the dipole capping layer 13 of the PMOS region and is provided to selectively remove only the capping layer 13 of the NMOS region. The first pattern 14 is formed of a material having an etching selectivity with the dipole capping layer 13.

Referring to FIG. 3C, the dipole capping layer 13 (refer to FIG. 3B) of the NMOS region is etched by a desired thickness. The etched dipole capping layer 13 of the NMOS region is referred to as a second dipole capping layer 13B, and the dipole capping layer 13 of the PMOS region, which is not etched, is referred to as a first dipole capping layer 13A.

The second dipole capping layer 13B of the NMOS region is formed to a critical thickness or less where a dipole effect is not exhibited. For example, the etching process may be performed in such a manner that the second dipole capping layer 13B of the NMOS region remains to a thickness of at least 0.3 nm. Therefore, the dipole capping layer 13 (refer to FIG. 3B) is etched by a thickness of 0.2 nm to 1.2 nm. The etching process for the dipole capping layer 13 may be performed by wet etching.

Referring to FIG. 3D, a metal gate conductor layer 15 is formed on the first and second dipole capping layers 13A and 13B.

The metal gate conductor layer 15 may include any one layer or two or more layers selected from the group consisting of titanium nitride, titanium aluminum nitride, tantalum nitride, titanium silicon nitride, tantalum silicon nitride, tantalum titanium nitride, titanium silicide, and hafnium nitride.

A second mask pattern 16 is formed on the metal gate conductor layer 15 of the PMOS region. The second mask pattern 16 is formed by the following process: a photoresist layer is applied on the metal gate conductor layer 15 and then patterned through exposure and development so as to remain only on the metal gate conductor layer 15 of the PMOS region.

Referring to FIG. 3E, the metal gate conductor layer 15 (refer to FIG. 3D) of the NMOS region is removed by using the second mask pattern 16 as an etching barrier such that the metal gate conductive layer 15 remains only on the first dipole capping layer 13A of the PMOS region.

The metal gate conductor layer 15 (refer to FIG. 3D) remaining on the first dipole capping layer 13A of the PMOS region is hereafter referred to as a metal gate layer 15A.

As the metal gate layer 15A having a high work function is additionally formed in the PMOS region, silicide may be prevented from being formed at the interface with a subsequent polysilicon layer. Therefore, a phenomenon in which a larger threshold voltage variation occurs in the PMOS region than the NMOS region due to Fermi level pinning depending on the silicide may be controlled.

Referring to FIG. 3F, a polysilicon layer 17 is formed on the second dipole capping layer 13B of the NMOS region and the metal gate layer 15A of the PMOS region.

Although not illustrated, ion impurities may be implanted into the polysilicon layer 17 depending on the NMOS region or PMOS region.

Referring to FIG. 3G, patterning is performed on the NMOS region and the PMOS region, respectively, to form gate patterns.

The gate pattern of the NMOS region has a stacked structure of the gate dielectric layer 12, the second dipole capping layer 13B having a smaller thickness than the first dipole capping layer 13A, and the polysilicon gate 17B, and the gate pattern of the PMOS region has a stacked structure of the gate dielectric layer 12, the first dipole capping layer 13A, the metal gate layer 15A, and the polysilicon gate 17A.

A gate spacer 18 is formed on sidewalls of the respective gate patterns of the NMOS and PMOS regions.

Ion impurities are implanted into the substrate 10 at both sides of the gate pattern to form a source/drain region 19.

As the first and second dipole capping layers 13A and 13B having different thicknesses are formed in the PMOS and NMOS regions, respectively, an interaction and diffusion between the gate dielectric layer 12 and the gate conductors (the polysilicon gate of the NMOS region and the metal gate layer of the PMOS region) may be prevented and a threshold voltage Vt and a flat-band voltage Vfb may be stabilized.

In particular, the first dipole capping layer 13A of the PMOS region may be formed to more than the dipole critical thickness to stabilize the threshold voltage and the flat-band voltage through P-type dipole capping. Simultaneously, the first dipole capping layer 13A of the NMOS region may be formed to the dipole critical thickness or less to substantially prevent the degradation of threshold voltage and flat-band voltage caused by a P-type capping effect.

### Second Exemplary Embodiment

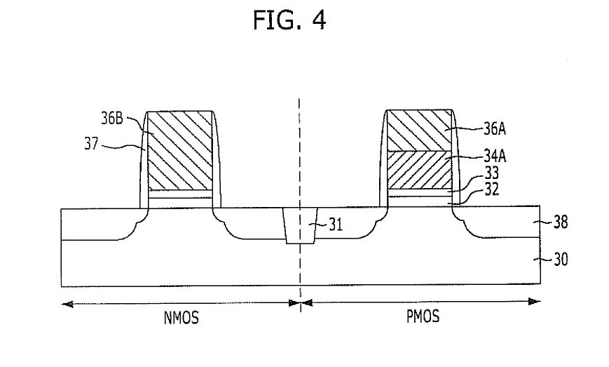

FIG. 4 is a cross-sectional view illustrating a semiconductor device in accordance with a second embodiment of the present invention.

Referring to FIG. 4, an isolation layer 31 is formed in a substrate 30 having NMOS and PMOS regions. Gate patterns are formed on the substrate 30 at the NMOS and PMOS regions, respectively.

The gate pattern of the NMOS region has a stacked structure of a gate dielectric layer 32, a dipole capping layer 33, and a polysilicon gate 36B, and the gate pattern of the PMOS region has a stacked structure of a gate dielectric layer 32, a dipole capping layer 33, a metal gate layer 34A, and a polysilicon gate 36A.

A gate spacer 37 is formed on sidewalls of the respective gate patterns of the NMOS and PMOS regions, and a source/drain region 38 is formed in the substrate 10 at both sides of the gate pattern.

The gate dielectric layer 32 of the NMOS and PMOS regions includes a single layer or multilayer. For example, the gate dielectric layer 32 has a single layer structure of a high-k dielectric layer or a multilayer structure including a high-k dielectric layer. The multilayer structure may include a structure in which a high-k dielectric layer is stacked on an oxide silicon layer (SiO₂) or an oxynitride silicon layer (SiON). At this time, the oxide silicon layer or oxynitride silicon layer is formed to a thickness of 1 nm or less.

Furthermore, the high-k dielectric layer is formed of a dielectric material having a dielectric constant of 3.9 or more. For example, the high-k dielectric layer includes any one layer or two or more layers selected from the group consisting of hafnium silicate, hafnium silicon oxynitride, hafnium oxide, zirconium oxide, titanium oxide, lanthanum oxide, hafnium aluminum oxide, strontium titanium oxide, and is formed to a thickness of 1 nm to 3 nm.

The dipole capping layers 33 of the PMOS and NMOS regions may be formed of a dielectric layer having a dielectric constant of eight or more, and forms a serial structure with the gate dielectric layer 32 thereunder to minimize a reduction of the gate dielectric. In particular, the dipole capping layer 33 may be formed to the dipole critical thickness or less (for example, 0.3 nm or less.

The metal gate layer 34A of the PMOS region includes any one layer or two or more layers selected from the group consisting of titanium nitride, titanium aluminum nitride, tantalum nitride, titanium silicon nitride, tantalum silicon nitride, tantalum titanium nitride, titanium silicide, and hafnium nitride.

As the dipole capping layers 33 having a dipole critical thickness or less are formed on the gate dielectric layers 32 of the PMOS and NMOS regions, respectively, an interaction and diffusion between the gate dielectric layer 32 and the metal gate layer 34A having a high work function may be substantially prevented in the PMOS region, and the formation of silicide at the interface between the polysilicon gate 36B and the gate dielectric layer 32 is substantially prevented in the NMOS region. Therefore, a threshold voltage Vt and a flat-band voltage Vfb may be stabilized and the reliability of the device may be improved.

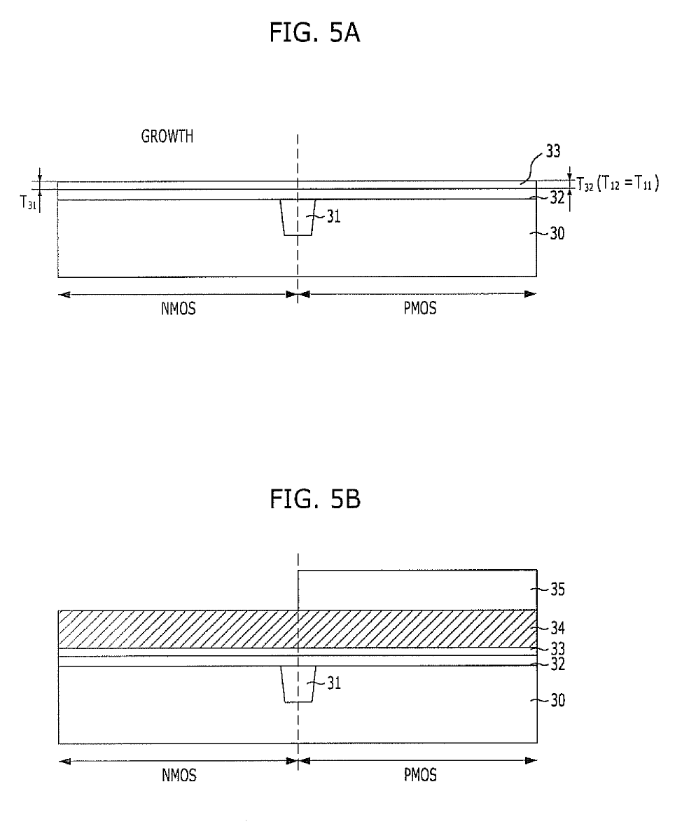

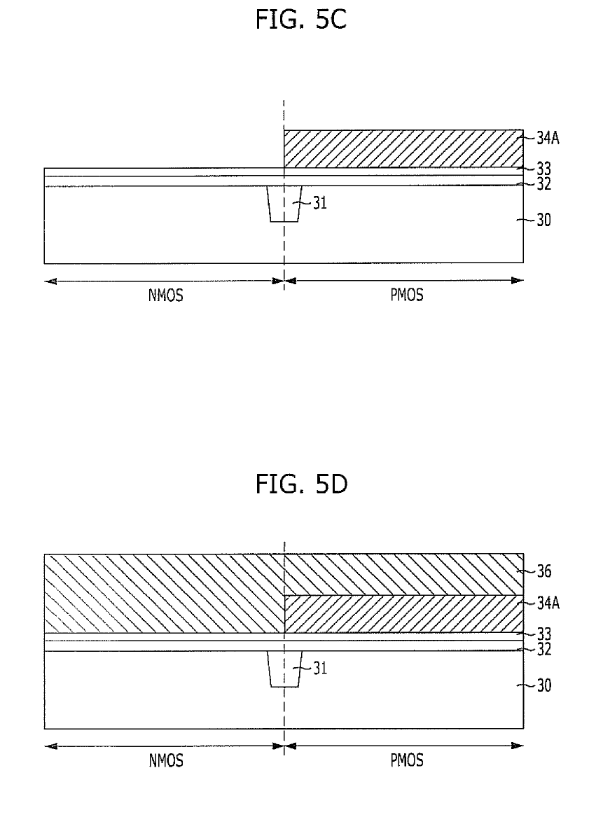

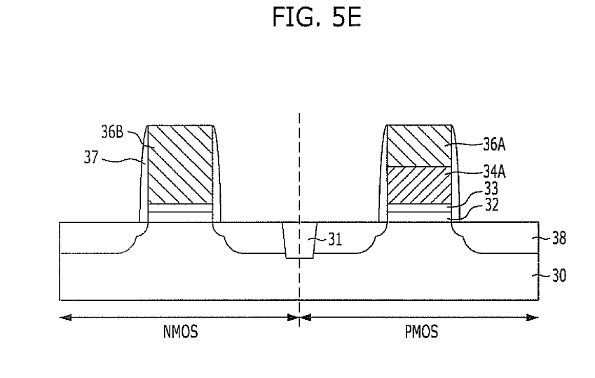

FIGS. 5A to 5E are cross-sectional views illustrating a method for fabricating a semiconductor device in accordance with the second embodiment of the present invention. FIGS. 5A to 5E are diagrams illustrating a method for fabricating the semiconductor device illustrated in FIG. 4. For purposes of illustration, the same reference numerals as those of FIG. 4 will be used.

Referring to FIG. 5A, an isolation layer 31 is formed in a substrate 30 having NMOS and PMOS regions. The isolation layer 31 may be formed by an STI process.

A gate dielectric layer 32 is formed on the substrate 30. The gate dielectric layer 32 includes a single layer or multiple layers. For example, the gate electric layer 32 may have a single layer structure of a high-k dielectric layer or a multilayer structure including a high-k dielectric layer. The multilayer structure may include a structure in which a high-k dielectric layer is stacked on an oxide silicon layer (SiO₂) or oxynitride silicon layer (SiON). At this time, the oxide silicon layer or oxynitride silicon layer is formed to a thickness of 1 nm or less.

Furthermore, the high-k dielectric layer is formed of a dielectric layer having a dielectric constant of 3.9 or more. For example, the high-k dielectric layer may include any one layer or two or more layers selected from the group consisting of hafnium silicate, hafnium silicon oxynitride, hafnium oxide, zirconium oxide, titanium oxide, lanthanum oxide, hafnium aluminum oxide, strontium titanium oxide, and is formed to a thickness of 1 nm to 3 nm.

A dipole capping layer 33 is formed on the gate dielectric layer 32. The dipole capping layer 33 serves to substantially prevent an interaction between the gate dielectric layer 12 and a subsequent gate conductor.

The dipole capping layer 33 may be formed of a dielectric layer having a dielectric constant of 8 or more, and formed to the same thickness (T₃₁=T₃₂) for the NMOS and PMOS regions. In particular, the dipole capping layer 33 may be formed to the dipole critical thickness or less (for example, 0.3 nm or less).

Referring to FIG. 5B, a metal gate conductor layer 34 is formed on the dipole capping layer 33.

The metal gate conductor layer 34 may include any one layer or two or more layers selected from the group consisting of titanium nitride, titanium aluminum nitride, tantalum nitride, titanium silicon nitride, tantalum silicon nitride, tantalum titanium nitride, titanium silicide, and hafnium nitride.

A mask pattern 35 is formed on the metal gate conductor layer 34 of the PMOS region. The mask pattern 35 is formed by the following process: a photoresist layer is applied on the metal gate conductor layer 34 and then patterned through exposure and development so as to remain only on the metal gate conductor layer 34 of the PMOS region.

Referring to FIG. 5C, the metal gate conductor layer 34 (refer to FIG. 5B) of the NMOS region is removed by using the mask pattern 35 as an etching barrier such that the metal gate conductive layer 34 remains only on the dipole capping layer 33 of the PMOS region.

The metal gate conductor layer 34 remaining on the first dipole capping layer 13A of the PMOS region is hereafter referred to as a metal gate layer 34A.

As the metal gate layer 34A having a high work function is additionally formed in the PMOS region, silicide may be prevented from being formed at the interface with a subsequent polysilicon layer. Therefore, a phenomenon in which a larger threshold voltage variation occurs in the PMOS region than the NMOS region due to Fermi level pinning depending on the silicide may be controlled.

Referring to FIG. 5D, a polysilicon layer 36 is formed on the dipole capping layer 33 of the NMOS region and the metal gate layer 34A of the PMOS region.

Although not illustrated, ion impurities may be implanted into the polysilicon layer 36 depending on the NMOS region or PMOS region.

Referring to FIG. 5E, patterning is performed on the NMOS region and the PMOS region, respectively, to form gate patterns.

The gate pattern of the NMOS region has a stacked structure of the gate dielectric layer 32, the dipole capping layer 33, and the polysilicon gate 36B, and the gate pattern of the PMOS region has a stacked structure of the gate dielectric layer 32, the dipole capping layer 33, the metal gate layer 34A, and the polysilicon gate 36A.

A gate spacer 37 is formed on sidewalls of the respective gate patterns of the NMOS and PMOS regions.

Ion impurities are implanted into the substrate 30 at both sides of the gate pattern to form a source/drain region 38.

As the dipole capping layers 33 having a dipole critical thickness or less are formed on the gate dielectric layers 32 of the PMOS and NMOS regions, respectively, an interaction and diffusion between the gate dielectric layer 32 and the metal gate layer 34A having a high work function may be substantially prevented in the PMOS region, and the formation of silicide at the interface between the polysilicon gate 36B and the gate dielectric layer 32 may be substantially prevented in the NMOS region. Therefore, a threshold voltage Vt and a flat-band voltage Vfb may be stabilized and the reliability of the device may be improved.

In accordance with the embodiments of the present invention, the P-type dipole capping layer is formed in the PMOS region to control a threshold voltage and stabilize a flat-band voltage. Therefore, the adequate reliability of the device may be obtained.

Furthermore, as the dipole capping layer having different thicknesses are formed in the PMOS and NMOS regions, respectively, the threshold voltage may be controlled in the PMOS region, and an interface reaction may be substantially prevented in the NMOS region.

Furthermore, an oxidation reaction and diffusion between the metal gate layer ad the gate dielectric layer may be substantially prevented, and the formation of silicide at the interface between the polysilicon gate and the gate dielectric layer may be substantially prevented.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a semiconductor device, comprising:
forming a gate dielectric layer over a substrate;
forming a dipole capping layer over the gate dielectric layer;
stacking a metal gate layer and a polysilicon layer over the dipole capping layer; and
forming a gate pattern by etching the polysilicon layer, the metal gate layer, the dipole capping layer, and the gate dielectric layer.

2. The method of claim 1, wherein, when the substrate comprises a PMOS region and the dipole capping is formed in the PMOS region, the dipole capping layer is formed of a P-type dipole capping layer.

3. The method of claim 1, where, when the substrate comprises an NMOS region and the dipole capping is formed in the NMOS region, the dipole capping layer is formed of an N-type dipole capping layer.

4. The method of claim 2, wherein the dipole capping layer comprises a metal insulator.

5. The method of claim 2, wherein the dipole capping layer comprises any one selected from the group consisting of aluminum oxide (Al₂O₃), aluminum oxynitride (AlON), and aluminum nitride (AlN).

6. A method for fabricating a semiconductor device, comprising:
forming a gate dielectric layer over a substrate having NMOS and PMOS regions;
forming dipole capping layers having different thicknesses over the gate dielectric layer in the NMOS and PMOS regions, respectively;
forming a metal gate layer over the dipole capping layer of the PMOS region;
forming a polysilicon layer over the dipole capping layer of the NMOS region and the metal gate layer of the PMOS region; and
forming gate patterns in the NMOS and PMOS regions, respectively, through patterning.

7. The method of claim 6, wherein the dipole capping layer is formed of a metal insulator.

8. The method of claim 6, wherein the dipole capping layer comprises any one selected from the group consisting of Al₂O₃, AlON, and AlN.

9. The method of claim 6, wherein the dipole capping layer of the NMOS region is formed with a smaller thickness than the dipole capping layer of the PMOS region.

10. The method of claim 9, wherein the dipole capping layer of the NMOS region is formed with a thickness equal to or less than a dipole critical thickness.

11. The method of claim 9, wherein the dipole capping layer of the NMOS region is formed to a thickness of 0.3 nm or less.

12. The method of claim 9, wherein the dipole capping layer of the PMOS region is formed to a thickness of 0.5 nm to 1.5 nm.

13. The method of claim 6, wherein the metal gate layer comprises any one layer or tow or more layers selected from the group consisting of titanium nitride, titanium aluminum nitride, tantalum nitride, titanium silicon nitride, tantalum silicon nitride, tantalum titanium nitride, titanium silicide, and hafnium nitride.

14. The method of claim 6, wherein the forming of the dipole capping layers comprises:
forming a first dipole capping layer over the gate dielectric layer of the NMOS and PMOM regions;
selectively removing the first dipole capping layer of the NMOS region; and
growing a second dipole capping layer over the gate dielectric layer of the NMOS region such that the second dipole capping layer has a smaller thickness than the first dipole capping layer.

15. The method of claim 6, wherein the forming of the dipole capping layers comprises:
forming a dipole capping layer over the gate dielectric layer at the NMOS and PMOS regions; and
etching the dipole capping layer of the NMOS region.

16. A semiconductor device comprising:
a gate dielectric layer formed over a substrate;
a dipole capping layer formed over the gate dielectric layer;
a metal gate layer formed over the dipole capping layer; and
a gate pattern having a polysilicon layer formed over the metal gate layer.

17. The semiconductor device of claim 16, wherein the dipole capping layer comprises a metal insulator.

18. The semiconductor device of claim 16, wherein the dipole capping layer comprises any one selected from the group consisting of Al₂O₃, AlON, and AlN.

19. The semiconductor device of claim 16, wherein the substrate comprises a PMOS region.

20. A method for fabricating a semiconductor device, comprising:
forming a gate dielectric layer over a substrate having NMOS and PMOS regions;
forming a dipole capping layer over the gate dielectric layer in the NMOS and PMOS regions;
forming a metal gate layer over the dipole capping layer of the PMOS region;
forming a polysilicon layer over the dipole capping layer of the NMOS region and the metal gate layer of the PMOS region; and
forming gate patterns in the NMOS and PMOS regions, respectively, through pattering.

21. The method of claim 20, wherein the dipole capping layer is formed of a dielectric layer having a dielectric constant of 8 or more.
